(19) United States
(12) Patent Application Publication
(10) Pub. No.: US 2025/0142869 A1
(43) Pub. Date: May 1, 2025

(54) POWER FINFETS WITH ALTERNATING SHIELDING REGIONS AND ONE-PIECE CONTROL ELECTRODES AND METHODS FOR PRODUCING THEM

(71) Applicant: Robert Bosch GmbH, Stuttgart (DE)

(72) Inventor: Daniel Krebs, Aufhausen (DE)

(21) Appl. No.: 18/905,808

(22) Filed: Oct. 3, 2024

(30) Foreign Application Priority Data
Oct. 30, 2023 (DE) 10 2023 210 713.9

(51) Int. Cl. H01L 29/78; H01L 21/04; H01L 21/3065; H01L 29/16; H01L 29/20; H01L 29/423

(52) U.S. Cl. CPC H10D 30/62; H01L 21/046; H01L 21/3065; H10D 62/8325; H10D 62/8503; H10D 64/513

(57) ABSTRACT

A method for producing power FinFETs with one-piece control electrodes. The method includes: creating a first structured mask; creating first trenches below first open regions by a first etching process starting from the front side of the semiconductor body and extending into the drift layer; creating shielding regions below the first trenches by a first implantation process; applying an isotropic oxide layer to the front side of the semiconductor body; creating a second structured mask; creating second trenches below second open regions by a third etching process; oxidizing the front side such that a further oxide layer is disposed on the front side; widening the first trenches and the second trenches by a fourth etching process; applying a polysilicon layer to the front side of the semiconductor body such that the first trenches and the second trenches are completely filled; and activating the shielding regions by means of annealing.

### CROSS REFERENCE

The present application claims the benefit under 35 U.S.C. § 119 of German Patent Application No. DE 10 2023 210 713.9 filed on Oct. 30, 2023, which is expressly incorporated herein by reference in its entirety.

### FIELD

The present invention relates to methods for producing power FinFETs with alternating shielding regions and one-piece control electrodes and power FinFETs with alternating shielding regions and one-piece control electrodes.

### BACKGROUND INFORMATION

Semiconductors with a wide band gap, such as SiC or GaN, are used in power electronics. Typically, power MOSFETs with a vertical channel region are used.

In order to increase the breakdown voltage of such power MOSFETs, shielding regions are disposed below the trenches. These shielding regions can be connected to the source regions by means of a contact in the trenches, so that two-part control electrodes are formed within the trenches as shown in German Patent Application No. DE 102 24 201 B4, for example.

A disadvantage of this can be, for example, that the trenches have to be very wide, so that the pitch dimension and the on-resistance of the power MOSFET, for instance, are large. A form factor can be large. The method for producing two-part control electrodes can moreover be laborious.

Between the shielding regions, which are usually p-doped, a so-called JFET is formed between two adjacent trenches and serves to limit the current through the channel region in the event of a short-circuit. For this purpose, p-doped shielding regions are implanted with the aid of a lithographically structured mask.

A disadvantage of this can be, for example, that this causes the distances between two p-doped shielding regions to be subjected to process fluctuations that affect the limitation of the short-circuit current.

An object of the present invention is to overcome these and other disadvantages.

### SUMMARY

The present invention provides methods for producing power FinFETs with alternating shielding regions and one-piece control electrodes and power FinFETs with alternating shielding regions and one-piece control electrodes.

Preferred embodiments of the present invention are disclosed herein.

According to a first aspect, the present invention relates to a method for producing power FinFETs with one-piece control electrodes and a semiconductor body which comprises a second connection region and a drift layer, wherein the second connection region forms a front side of the semiconductor body. According to an example embodiment of the present invention, the method comprises creating a first structured mask on the front side of the semiconductor body by means of a lithography step, wherein the first mask comprises oxide regions and first open regions, wherein the first open regions expose the front side of the semiconductor body and creating first trenches below the first open regions by means of a first etching process starting from the front side of the semiconductor body and extending into the drift layer. The method also comprises creating shielding regions below the first trenches by means of a first implantation process. The method comprises applying an isotropic oxide layer to the front side of the semiconductor body, creating a second structured mask by means of a second etching process such that the isotropic oxide layer comprises second open regions, wherein the second open regions expose the front side of the semiconductor body and creating second trenches below the second open regions by means of a third etching process starting from the front side and extending into the drift layer, wherein the second trenches are disposed substantially parallel to the first trenches and the first trenches and the second trenches alternate, wherein the second trenches have a smaller width than the first trenches. The method also comprises oxidizing the front side such that a further oxide layer is disposed on the front side and widening the first trenches and the second trenches by means of a fourth etching process such that fins are created between the first trenches and the second trenches, the fins have a width less than 500 nm. The method comprises applying a polysilicon layer to the front side of the semiconductor body such that the first trenches and the second trenches are completely filled and activating the shielding regions by means of annealing.

An advantage of this can be that it creates a short-circuit current-limiting effect between the shielding region and the side walls of the second trenches. This allows process fluctuations to be tolerated. It also makes it possible to reduce a distance between the shielding regions.

In a further development of the present invention, the first structured mask comprises nitride regions, wherein the oxide regions are disposed on the nitride regions.

An advantage of this can be that it prevents oxidation of the upper side of the fins.

In a further embodiment of the present invention, spreading regions are created below the second trenches by means of a second implantation process, wherein the second implantation energy has a value between 200 keV and 2500 keV.

An advantage of this can be that the on-resistance can be reduced.

In a further development of the present invention, the first etching process, the second etching process and the third etching process are anisotropic plasma etching processes.

An advantage of this can be that the structured masks can be transferred to the underlying layers with minimal widening.

In one example embodiment of the present invention, the first implantation process has a first implantation energy in the range of 30 keV to 2700 keV.

An advantage of this can be that the shielding regions below the gate oxide to be protected are created in the trench floor so that a maximum shielding effect is achieved without pitch loss.

According to a second aspect, the present invention relates to a power FinFET with one-piece control electrodes and a semiconductor body comprising a drift layer and a second connection region. The second connection region is disposed above the drift layer and first trenches and second trenches extend from the second connection region into the drift layer. First trenches and second trenches are disposed such that they alternate, wherein the second trenches have a smaller width than the first trenches and shielding regions are disposed below the first trenches. The shielding regions directly adjoin the first trenches, wherein the shielding regions are electrically conductively connected to source regions and the electrically conductive connections are not disposed within the first trenches (206). A one-piece control electrode is respectively disposed within the first trenches, wherein the one respective one-piece control electrode is electrically insulated from the shielding region below the first trenches. Fins are disposed between the first trenches and the second trenches, wherein the fins have a maximum width of 500 nm.

An advantage of this can be that a short-circuit current can be limited by the space charge zone of the shielding regions and the opposite trench wall of a second trench. It can moreover be advantageous that the influence of the process variability on the short-circuit current and on-resistance can be reduced.

In a further development of the present invention, spreading regions are disposed below the second trenches.

An advantage of this can be that the current spreading can be increased and/or the on-resistance can be reduced.

In a further embodiment of the present invention, the shielding regions are p-doped and have a dopant concentration of at least 1E18/cm³.

An advantage of this can be that high implantation doses can be introduced cost-effectively below the trench floor.

In one example embodiment of the present invention, the semiconductor body comprises SiC.

An advantage of this can be that aluminum, which is easy to activate, can be used for implantation.

In a further embodiment of the present invention, the semiconductor body comprises GaN.

An advantage of this can be that the critical field strength and the electron mobility can be increased.

Further advantages will emerge from the following description of embodiment examples.

### BRIEF DESCRIPTION OF THE DRAWINGS

The present invention is explained in the following with reference to preferred embodiments and the figures.

FIG. 1 shows a method for producing a power FinFET with alternating shielding regions and one-piece control electrodes, according to an example embodiment of the present invention.

FIG. 2 shows a power FinFET with alternating shielding regions and one-piece control electrodes, according to an example embodiment of the present invention.

### DETAILED DESCRIPTION OF EXAMPLE EMBODIMENTS

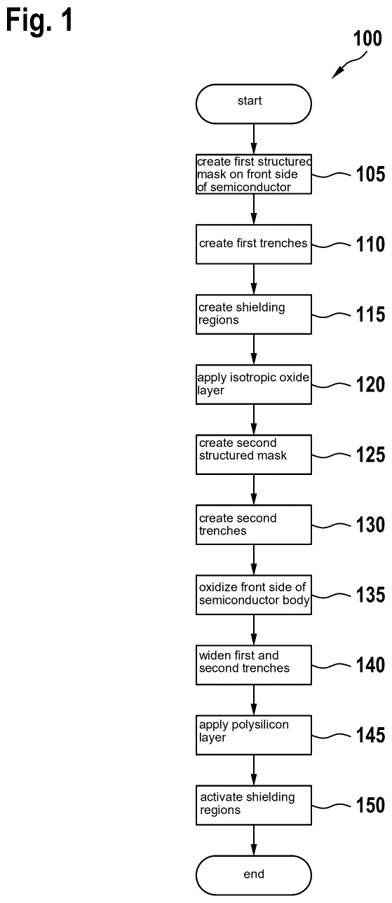

FIG. 1 shows a method for producing a power FinFET with alternating shielding regions without two-part control electrodes. The control electrodes are formed in one piece. At least one control electrode can generally be formed in one piece. Shielding regions of the power FinFET are connected to source regions. The connections are not disposed within the trenches of the power FinFET. The source regions can instead be electrically conductively connected, for example by means of a contact at the end of a cell field, or by a deep connection region implanted, for instance at periodic intervals, along a fin.

The power FinFET comprises a semiconductor body, which comprises SiC or GaN, for example, a second connection region and a drift layer, wherein the second connection region forms a front side of the semiconductor body.

The method can comprise a step 105, in which a first structured mask is created on the front side of the semiconductor body by means of a lithography step. The first structured mask can comprise oxide regions and first open regions that expose the front side of the semiconductor body.

In a step 110, first trenches can be created below the first open regions by means of a first etching process starting from the front side of the semiconductor body and extending into the drift layer.

In a step 115, shielding regions below the first trenches can be created by means of a first implantation process with a first implantation energy. The first implantation energy is between 30 keV and 2700 keV. The shielding regions can be p-doped.

In a step 120, an isotropic oxide layer can be applied to the front side of the semiconductor body.

In a step 125, a second structured mask can be created by means of a second etching process such that the isotropic oxide layer comprises second open regions and the second open regions expose the front side of the semiconductor body.

In a step 130, second trenches can be created below the second open regions by means of a third etching process starting from the front side of the semiconductor body and extending into the drift layer. The second trenches are preferably disposed parallel to the first trenches and alternate. The second trenches can have a smaller width than the first trenches.

In other words, a self-aligned or self-adjusted mask can be created in step 125. As a result, the second trenches can be produced sublithographically in step 130 by means of a mask reversal process, and the width of the mesas between the first trenches and the second trenches or the pitch can be determined by the thickness of the isotropic oxide layer. A precise adjustment between the shielding regions below the first trenches and the opposite side walls of the second trenches is possible, too, so that optimal setting of the on-resistance, the short-circuit current and the field in the oxide of the trench floor of the second trenches can be achieved.

In a step 135, the front side of the semiconductor body can be oxidized such that a further oxide layer is disposed on the front side of the semiconductor body. The further oxide layer has a thickness of at least 10 nm.

In a step 140, the first trenches and the second trenches can be widened by means of a fourth etching process such that fins, which can have a width smaller than 500 nm, preferably a width in the range between 400 and 50 nm, even more preferably a width in the range between 200 and 50 nm, for example, are created between the first trenches and the second trenches. The oxide of step 135 can selectively be wet chemically etched.

Depending on the fin width to be achieved, steps 135 and 140 can be carried out cyclically. In other words, the front side of the semiconductor body can be oxidized several times. An etching step can be carried out between the oxidation steps. The widening of the trenches can thus be carried out without adjustment, because the lateral oxidation rate outweighs the vertical oxidation rate by a factor of about two.

In a step 145, a polysilicon layer can be applied to the front side of the semiconductor body such that the first trenches and the second trenches are completely filled. During subsequent etching, this can lead to there not only being one spacer that remains on the trench sidewall, but all of the first and second trenches are completely filled as before. Alternatively or additionally, the first trenches and/or the second trenches can be partially or completely filled in separate steps.

In a subsequent step 150, the shielding regions can be activated by means of annealing. The annealing is typically carried out at 1700° C.

With the help of the method according to the present invention, the shielding regions below the first trenches are further apart from one another than the shielding regions are from the opposite trench walls or side walls of the second trenches. The short-circuit current is consequently not limited by the coming together of the space charge zones of two shielding regions, but instead by the space charge zone of a respective p-doped shielding region which forces or pushes the current against the opposite trench wall of a second trench. The low sensitivity to process variability is achieved by the fact that, in the event of a short-circuit, due to the positive gate voltage, the trench wall of the respective second trench forms an accumulation channel that cannot be overcome by the space charge zone of the p-doped shielding region.

The first etching process, the second etching process and/or the third etching process can be anisotropic etching processes. The fourth etching process can be isotropic. In the case of a Sic semiconductor body, the first and/or the third etching process can select between SiC, that is being etched, and SiO₂, SiN and Si that are not being etched. In the case of a SiC semiconductor body, the second etching process and/or the fourth etching process can select between SiO₂, that is being etched, and SiC, SiN and Si that are not being etched.

In one embodiment example, the first structured mask comprises nitride regions which are disposed between the front side and the oxide regions. The nitride regions protect the front side or the surface of the fins, because this prevents oxidation of the upper side of the fins in step 140. The nitride regions can be removed in an intermediate step between step 145 and step 150 not shown in FIG. 1.

In another embodiment example, spreading regions can be implanted below the second trenches by means of a second implantation process. The spreading regions can be n-doped and can have a higher doping than the n-doped drift layer. This makes it possible to increase the current spreading effect below the second trenches. The second implantation process can have a second implantation energy that has a value between 200 keV and 2500 keV.

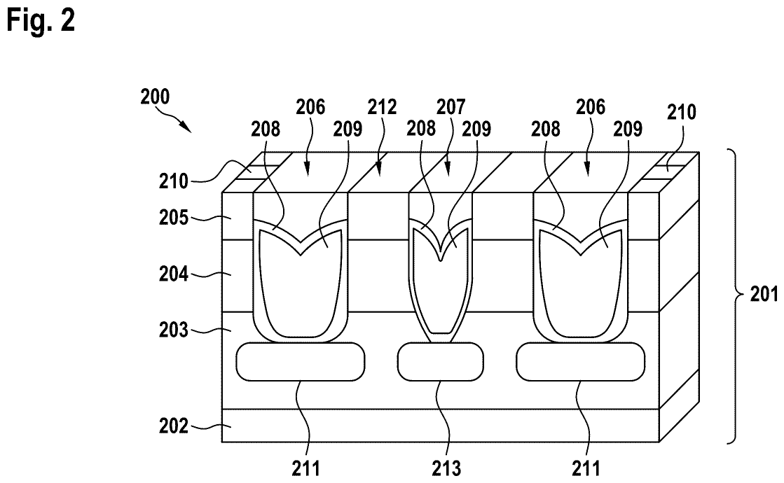

FIG. 2 shows a power FinFET 200 with alternating shielding regions without two-part control electrodes 209. The control electrodes 209 are in one piece. The power FinFET 200 comprises a semiconductor body 201 comprising a first connection region 202, a drift layer 203, a channel region 204 and a second connection region 205. The first connection region 202 functions as a drain connection and the second connection region 205 functions as a source connection. The drift layer 203 is disposed on the first connection region 202, the channel region 204 is disposed on the drift layer 203, and the second connection region 205 is disposed on the channel region 204. The second connection region 205 functions as the front side of the semiconductor body 201.

Starting from the front side of the semiconductor body 201, first trenches 206 and second trenches 207 extend into the drift layer 203, wherein the second trenches 207 have a smaller width than the first trenches 206. The first trenches 206 and the second trenches 207 are disposed such that they alternate. Disposed below the first trenches 206 are shielding regions 211, which are preferably p-doped and directly adjoin a trench floor of the first trenches 206. The dopant concentration of the shielding regions 211 is at least 1E18/cm³. The shielding regions 211 are electrically conductively connected to source regions 210 that are not disposed within the trenches, but rather by means of a contact at the end of a cell field, for example, or by a deep connection region implanted, for instance at periodic intervals, along a fin as partly illustrated in FIG. 2. The control electrode 209 can function as a gate connection. Dividing a control electrode 209 into two parts can be omitted completely or at least in part. One, several or all of the control electrodes 209 can therefore be one-piece. Control electrodes 209 are electrically insulated from the shielding region 211 by means of an oxide layer 208. Fins 212, which can have a width less than 500 nm, for example, preferably a width in the range between 400 and 50 nm, more preferably a width in the range of between 200 and 50 nm, are disposed between the first trenches 206 and the second trenches 207.

The semiconductor body 201 can comprise SiC and/or GaN.

In one embodiment example, spreading regions 213 are disposed below the second trenches 207. The spreading regions 213 can be n-doped. They can have a higher doping than the drift layer 203, which can likewise be n-doped. Shielding regions 211 and spreading regions 213 can be disposed alternately, in particular in an alternating manner, or in a periodic pattern. A distance between directly adjacent shielding regions 211 can be in the range between 800 and 1000 nm, preferably in the range between 850 and 950 nm. More preferably, a distance between directly adjacent shielding regions can be 900 nm.

Power FinFETs are used in DC/DC converters and inverters of an electric drive train of electric or hybrid vehicles, for example, and also in vehicle chargers.

What is claimed is:

1. A method for producing a power FinFET with one-piece control electrodes, wherein the power FinFET includes a semiconductor body including a second connection region and a drift layer, wherein the second connection region forms a front side of the semiconductor body, the method comprising the following steps:
creating a first structured mask on the front side of the semiconductor body using a lithography step, wherein the first structured mask includes oxide regions and first open regions and the first open regions expose the front side of the semiconductor body;
creating first trenches below the first open regions using a first etching process starting from the front side of the semiconductor body and extending into the drift layer;
creating shielding regions below the first trenches using a first implantation process;
applying an isotropic oxide layer to the front side of the semiconductor body;
creating a second structured mask by means of a second etching process such that the isotropic oxide layer includes second open regions, and the second open regions expose the front side of the semiconductor body;
creating second trenches below the second open regions using a third etching process starting from the front side and extending into the drift layer, wherein the second trenches are disposed substantially parallel to the first trenches and the first trenches and the second trenches alternate, wherein the second trenches have a smaller width than the first trenches;
oxidizing the front side such that a further oxide layer is disposed on the front side,
widening the first trenches and the second trenches by a fourth etching process such that fins are created between the first trenches and the second trenches, wherein the fins have a width less than 500 nm;
applying a polysilicon layer to the front side of the semiconductor body such that the first trenches and the second trenches are completely filled; and
activating the shielding regions by annealing.

2. The method according to claim 1, wherein the first structured mask includes nitride regions and the oxide regions are disposed on the nitride regions.

3. The method according to claim 1, wherein spreading regions are created below the second trenches by a second implantation process, wherein a second implantation energy has a value between 200 keV and 2500 keV.

4. The method according to claim 1, wherein the first etching process, the second etching process, and the third etching process are anisotropic plasma etching processes.

5. The method according to claim 1, wherein the first implantation process has a first implantation energy in a range of 30 keV to 2700 keV.

6. A power-FinFET, comprising:
one-piece control electrodes; and
a semiconductor body including a drift layer and a second connection region, wherein the second connection region is disposed above the drift layer, and first trenches and second trenches extend from the second connection region into the drift layer, wherein the first trenches and the second trenches are disposed such that they alternate, and the second trenches have a smaller width than the first trenches, wherein shielding regions are disposed below the first trenches, wherein the shielding regions directly adjoin the first trenches and the shielding regions are electrically conductively connected to source regions, wherein the electrically conductive connections are not disposed within the first trenches, wherein a respective one-piece control electrode is respectively disposed within each of the first trenches and each respective one-piece control electrode is electrically insulated from the shielding region below the first trenches, and wherein fins are disposed between the first trenches and the second trenches and the fins have a maximum width of 500 nm.

7. The power FinFET according to claim 6, wherein spreading regions are disposed below the second trenches.

8. The power FinFET according to claim 6, wherein the shielding regions are p-doped and have a dopant concentration of at least 1E18/cm³.

9. The power FinFET according to claim 6, wherein the semiconductor body includes SiC.

10. The power FinFET according to claim 6, wherein the semiconductor body includes GaN.
